(19) United States
(12) Patent Application Publication
(10) Pub. No.: US 2024/0258423 A1
(43) Pub. Date: Aug. 1, 2024

(54) SEMICONDUCTOR DEVICE

(71) Applicant: Sanan Japan Technology Corporation, Tokyo (JP)

(72) Inventors: Sunao Aya, Tokyo (JP); Hiroshi Nakamura, Tokyo (JP); Shinichi Shioi, Tokyo (JP)

(73) Assignee: Sanan Japan Technology Corporation, Tokyo (JP)

(21) Appl. No.: 18/423,118

(22) Filed: Jan. 25, 2024

(30) Foreign Application Priority Data
Jan. 26, 2023 (JP) 2023-010562

(51) Int. Cl. H01L 29/78; H01L 29/08; H01L 29/10; H01L 29/16

(52) U.S. Cl. CPC H01L 29/7813; H01L 29/0873; H01L 29/1095; H01L 29/1608; H01L 29/7806

(57) ABSTRACT

An example semiconductor device includes a drain layer formed of a first conductivity semiconductor, a drift layer formed of the first conductivity semiconductor and on the drain layer, and a plurality of trench stripes having longitudinal directions and lateral directions formed of a second conductivity semiconductor and formed on the drift layer, wherein the longitudinal directions of the plurality of trench stripes disposed toward at least two directions.

### CROSS-REFERENCE TO RELATED APPLICATION(S)

This application claims priority to Japanese Application No. 2023-010562, filed Jan. 26, 2023, which are incorporated herein by reference, in their entirety, for any purpose.

### BACKGROUND OF THE INVENTION

### Field of the Invention

The present invention relates to a semiconductor device.

### Background Art

A power semiconductor device (power device) such as an IGBT (Insulated Gate Bipolar Transistor) and a MOSFET (MOS Field Effect Transistor) is widely used as a semiconductor switch for a power supply of a large-capacity server, an uninterruptible power supply, and an inverter circuit such as an industrial motor and an automotive motor. A semiconductor substrate is processed thin in the front and back conductive power semiconductor device in order to improve an electrically-conductive performance typified by on-state characteristics or the like. Recently, in order to improve the cost and property side, semiconductor devices have been produced by an ultrathin wafer process thinned to about 50 μm based on a wafer material produced by FZ (Floating Zone) method. However, wafer warpage during the wafer process causes a problem in the trend of wafer thinning and film thickening of an electrode. Specifically, wafer chipping or cracking occurs when the wafer edge comes into contact with unexpected places during wafer handling. This occurs the problem that the manufacturing cost is increased because the manufacturing yield is lowered.

Patent Document 1 (JP2011-222898) discloses a technique for preventing wafers from such warping. A semiconductor wafer becomes a state warped convexly toward the frontside by stress based on the temperature difference at the time of film formation of the backside electrode when the backside electrode is formed on the backside of the semiconductor wafer by a vacuum film forming method. The backside of the semiconductor wafer is plasma-processed to remove deposits adhering to the backside of the semiconductor wafer. Along the wafer warpage of the semiconductor, a separation tape is attached to the backside of the semiconductor wafer in order to prevent the backside electrode contamination during the plating process and to suppress the wafer warpage. The semiconductor wafer keeps warped convexly to the frontside even after attaching the separation tape. Next, a plating film is formed on the surface of the semiconductor wafer by an electroless plating process. Then, the separation tape is peeled off from the semiconductor wafer. Thereafter, a semiconductor chip is cut out from the semiconductor wafer.

However, the technique shown in Patent Document 1 makes it difficult to control the manufacturing conditions such as the film forming conditions and the tape attaching conditions for maintaining stable quality. In addition, the number of processes is increased by applying the tape attaching and peeling steps to the wafer for the protection of the backside electrode. This inevitably increases the number of wafer handling and the probability of wafer breakage due to that. Further, this also increases the defect rate that there is a residue of the tape material on the backside electrode after the tape peeling during assembly. These cause a problem that makes it difficult to reduce manufacturing costs.

### SUMMARY OF THE INVENTION

Some examples described herein may address the above-described problems. Some examples described herein may have an object to provide a semiconductor device that facilitates the production of a semiconductor with a thinner wafer thickness by suppressing the wafer warpage and decreasing the difficulty of wafer handling, reduces on-resistance and improves heat dissipation.

In some examples, a semiconductor device includes a drain layer formed of a first conductivity semiconductor, a drift layer formed of the first conductivity semiconductor and on the drain layer, and a plurality of trench stripes having longitudinal directions and lateral directions formed of a second conductivity semiconductor and formed on the drift layer, wherein the longitudinal directions of the plurality of trench stripes disposed toward at least two directions.

### BRIEF DESCRIPTION OF THE DRAWING

FIG. 1 is a cross-sectional view of a semiconductor device according to a first embodiment.

FIG. 2 is a schematic top view of a semiconductor device according to the first embodiment.

FIG. 3 is a view of a crystal plane of a 4H silicon carbide crystal.

FIG. 4 is a view of the crystal plane of the 4H silicon carbide crystal from the (0001) plane and an outline drawing of a 4H silicon carbide substrate.

FIG. 5 is an explanatory diagram illustrating a method for producing the semiconductor device according to the first embodiment.

FIG. 6 is a schematic top view of the semiconductor device according to a second embodiment.

FIG. 7 is a schematic top view of the semiconductor device according to a third embodiment.

FIG. 8 is a schematic top view of the semiconductor device according to a fourth embodiment.

FIG. 9 is a schematic top view of the semiconductor device as a comparative example.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

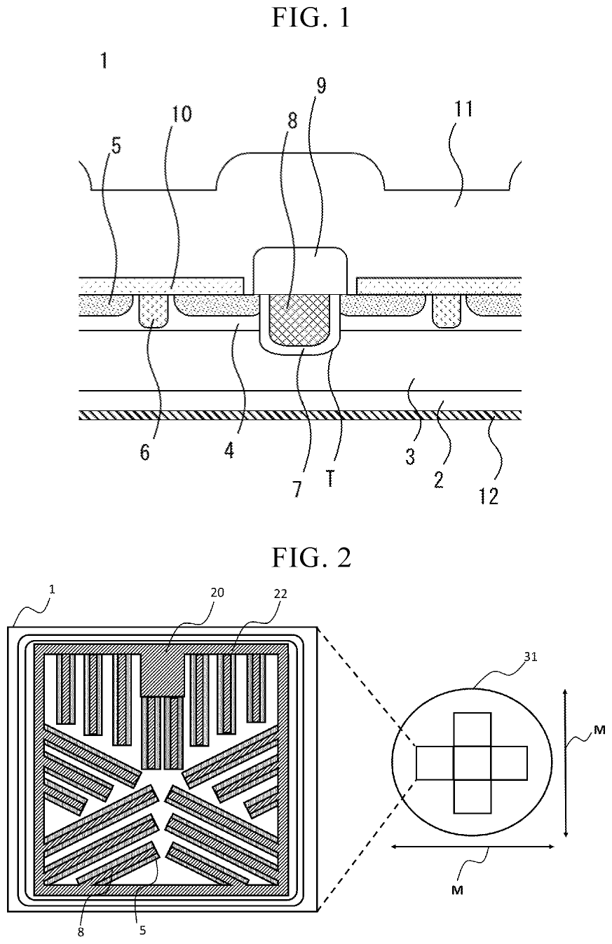

FIG. 1 is a cross-sectional view of a semiconductor device according to the first embodiment.

As shown in FIG. 1, a semiconductor device 1 includes a trench MOSFET of silicon carbide. The semiconductor device 1 includes a drain layer 2, a drift layer 3, a plurality of body layers 4, a plurality of source layers 5, a plurality of body contact layers 6, a plurality of gate insulating films 7, a plurality of gate electrode trench stripes 8, a plurality of interlayer insulating layers 9, a plurality of source electrode layers 10, a wire electrode layer 11 and a drain electrode layer 12. The trench T provided in a stripe shape extending in a depth direction of FIG. 1.

Only one each of the plurality of gate insulating films 7, the plurality of gate electrode trench stripes 8 and the plurality of interlayer insulating layers 9 are illustrated in FIG. 1.

The drain layer 2 is formed of a first conductivity type silicon carbide. The drain layer 2 is formed of such as n⁺ type 4H silicon carbide. For example, the drain layer 2 is formed using nitrogen as an impurity. The drift layer 3 is formed on the first surface of the drain layer 2 (the upper surface in FIG. 1). The drift layer 3 is formed of a first conductivity type silicon carbide having a lower impurity concentration than that of the drain layer 2. The drifting layer 3 includes a n type layer. For example, the drift layer 3 is formed on the drain layer 2 by means of epitaxial growth.

The plurality of body layers 4 are formed on the drift layer 3. The plurality of body layers 4 are formed of a second conductivity silicon carbide. The plurality of body layers 4 are such as p⁻ type layer. For example, the plurality of body layers 4 are formed by ion implantation technique using aluminum as an impurity. For example, the plurality of body layers 4 are formed by epitaxial method. The plurality of source layers 5 are formed on each of the plurality of body layers 4. The plurality of source layers 5 are formed of the first conductivity silicon carbide having a higher impurity concentration than that of the drift layer 3. The plurality of source layers 5 are n⁺ type layers for example. The plurality of source layers 5 are formed by an ion implantation technique using nitrogen as an impurity. The plurality of body contact layers 6 are formed on each of the plurality of body layers 4. The body contact layers 6 are surrounded by the source layers 5 in each of the plurality of body layers 4. The plurality of body contact layers 6 are formed of the second conductivity silicon carbide having a higher impurity concentration than that of the plurality of body layers 4. The plurality of body contact layers 6 are p′ type layers for example. For example, the plurality of body contact layers 6 are formed by ion implantation technique using aluminum as an impurity.

The plurality of gate insulating films 7 are formed in each interior of a plurality of trenches T that penetrate through the body layers 4 and the source layers 5 to the drift layers 3 in the adjacent body layer 4. The plurality of gate insulating film 7 are silicon dioxide for example. The plurality of gate insulating films 7 are aluminum oxide for example. The plurality of gate insulating films 7 are formed by thermal oxidation for example. The plurality of gate insulating films 7 are formed by CVD or ALD methods for example. The plurality of gate electrode trench stripes 8 are respectively formed on the plurality of gate insulating films 7 in each interior of the plurality of trenches T. For example, the plurality of gate electrode trench stripes 8 are formed of polysilicon by CVD method.

The plurality of interlayer insulating layers 9 are formed so as to cover each of the plurality of gate electrode trench stripes. For example, the plurality of interlayer insulating layers 9 are formed by CVD method. The plurality of source electrode layers 10 are formed corresponding to each of the plurality of body layers 4. The plurality of source electrode layers 10 are formed so as to come into contact with the source layers 5. The source electrode layer 10 may be formed across the body contact layers 6. For example, the plurality of source electrode layers 10 are formed of a film of Ni or the like with a sputtering method and by heat treatment. The plurality of source electrode layers 10 are formed by forming a film of Ti or the like by the sputtering method. The wire electrode layer 11 is formed so as to cover the plurality of source electrode layers 10. The wire electrode layer 11 is formed of an aluminum alloy or the like by the sputtering method for example.

The drain electrode layer 12 is formed on the second surface of the drain layer 2 (the lower surface in FIG. 1). For example, the drain electrode layer 12 are formed of a film of Ni or the like with the sputtering method and by heat treatment.

FIG. 2 is a schematic top view of a semiconductor device according to the first embodiment. As shown in FIG. 2, a gate pad 20, a gate electrode wiring 22 and the plurality of gate electrode trench stripes 8 are formed on the semiconductor device 1.

Further, the plurality of source layers 5 are formed to adjacent to the plurality of gate electrode trench stripes 8. Some of the plurality of gate electrode trench stripes 8 are connected directly to the gate pad 20. Also, some of the plurality of gate electrode trench stripes 8 are directly connected to the gate electrode wiring 22. As shown in FIG. 2, the direction of the plurality of gate electrode trench stripes 8 are arranged in three directions.

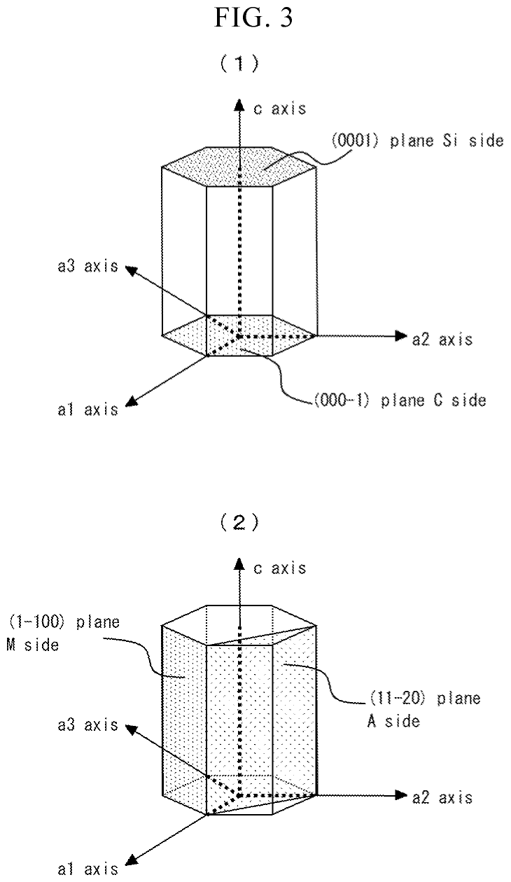

4H silicon carbide constituting the drift layer is hexagonal crystal of which the first major plane is a (0001) Si plane as shown in FIG. 3 part (1). A gate-channel portion of a trench-type MOSFET is formed perpendicularly on the main plane. When this happens, for example a (11−20) plane of the crystal orientation is desirable for the vertical plane formed as shown in FIG. 3 part (2).

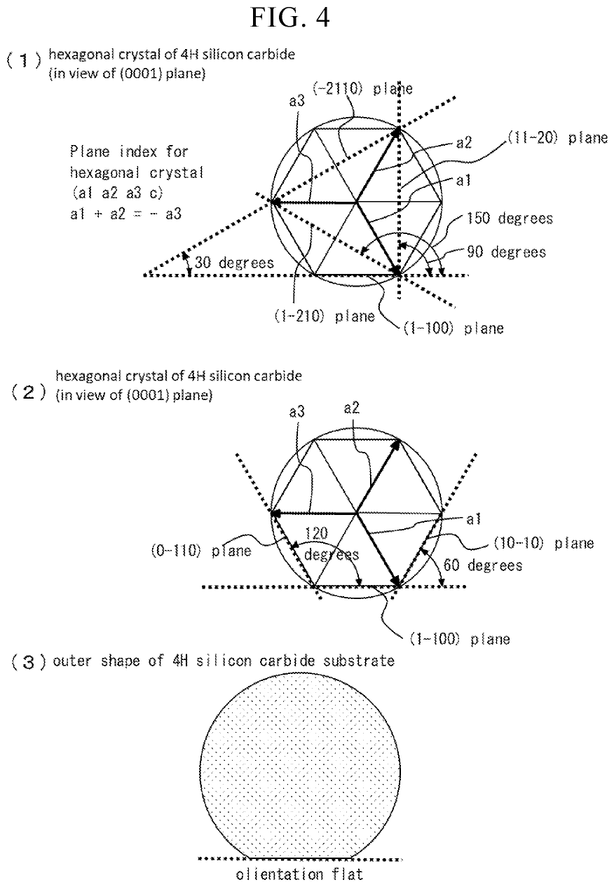

Since the hexagonal crystal is six-fold symmetry, it is desirable that a (1−210) plane and a (−2110) plane forming 60 degrees each other as other crystal surface as shown in FIG. 4 part (1). The outer shape of 4H silicon carbide substrate is shown in FIG. 4 part (3). Normally, the orientation flat for confirming the direction of the substrate and a (1−100) plane shown in FIG. 4 part (1) are generally the same. The angle between the orientation flat and the (1−100) plane of the crystal varies by +5 degrees due to producing errors. Therefore, it is desirable that the three longitudinal directions of the gate electrode trench stripes 8 are positioned between −5 degrees to 5 degrees, between 55 degrees to 65 degrees, or between 115 degrees to 125 degrees against the orientation flat. This can increase channel mobility.

As shown in FIG. 2, the three longitudinal directions of the plurality of gate electrode trench stripes 8 desirably be arranged substantially parallel to the (11−20) plane, the (1−210) plane and the (−2110) plane of the hexagonal crystal of the 4H silicon carbide. Alternatively, it is desirable that each three longitudinal directions of the plurality of gate electrode trench stripes 8 be arranged substantially parallel to three planes of the hexagonal crystal of the (1−100) planes, a (10−10) planes, and a (0−110) planes of 4H silicon carbide. This improves channel mobility.

Epitaxial growth of 4H silicon carbide may be grown with hexagonal crystals inclined by 4 or 8 degrees. Thus, for example, the (10−10) plane, the (0−110) plane, the (1−210) plane and the (−2110) plane of the cubic of 4H silicon carbide slightly changed from the angle in a top view.

For example, in the case of epitaxial growth with 4 degrees gradient, the angle formed by the (1−210) plane and the (−2110) plane is 30 degrees as shown in FIG. 4 part (1) in a top view of the cubic crystal. Meanwhile, it is 29.94 degrees in a top view of the wafer.

The three longitudinal directions of the plurality of gate electrode trench stripes 8 may be parallel (substantially parallel) to each plane including such errors and other production errors. Desirably, the three longitudinal directions of the plurality of gate electrode trench stripes 8 may be arranged in parallel (substantially parallel) with each plane within +0.2 degrees.

The angle formed by the orientation flat and the (1−100) plane of the crystal has variation of +5 degrees due to producing errors. Therefore, the three longitudinal directions of the gate electrode trench stripes 8 may be arranged between 25 degrees to 35 degrees, between 85 degrees to 95 degrees, or between 145 degrees to 155 degrees to the orientation flat. This allows channel mobility increased.

In the case of a notch-type wafer without an orientation flat, a plane perpendicular to a plane from the notch toward the center of the wafer can be regarded as an orientation flat (regarded orientation flat). The three longitudinal directions of the gate electrode trench stripes 8 may be arranged between 25 degrees and 35 degrees, between 85 degrees and 95 degrees, or between 145 degrees and 155 degrees to the regarded orientation flat. This allows channel mobility increased.

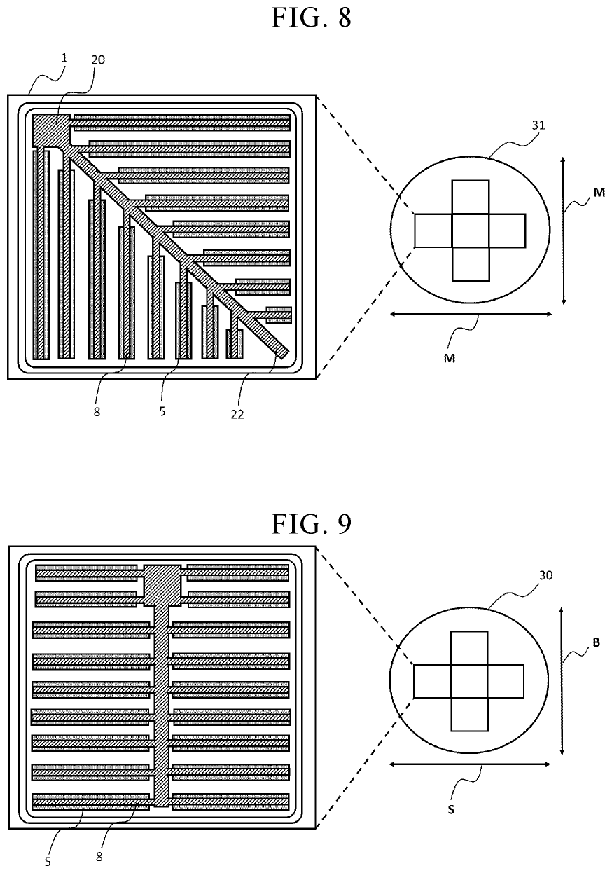

Here, FIG. 9 is a schematic top view of the semiconductor device as a comparative example. As shown in FIG. 9, the plurality of gate electrode trench stripes 8 are arranged in one direction in the longitudinal direction. A wafer 30 shown in FIG. 9 shows a state in which the plurality of semiconductor devices as the comparative examples before being segmented are arranged in an array.

The horizontal axis direction S of the wafer 30, the wafer warpage is small. The longitudinal direction B of the wafer 30, the wafer warpage is large. In a trench stripe trench-type MOSFET in which the plurality of gate electrode trench stripes 8 are arranged such that the longitudinal direction faces one direction, the anisotropy of warpage of the wafer is large. This is because stress is generated in each producing process such as burying polysilicon into trench and laser annealing. This leads to difficulties in wafer handling. Furthermore, there is a possibility that the on-resistance of the semiconductor device is increased by the piezoelectric effect.

FIG. 2 also shows a wafer 31 in which the semiconductor device 1 according to the first embodiment before being segmented is arranged in an array. Both the horizontal axis direction M and the vertical axis direction M of the wafer 31, the wafer warpage is moderate. In a trench stripe trench-type MOSFET in which the plurality of gate electrode trench stripes 8 are arranged so that the longitudinal direction faces at least two directions, anisotropy of warpage of the wafer is reduced.

In particular, when the sum of the lengths of the gate electrode stripes in each of the three directions is equal, the anisotropy of the warpage of the wafer is reduced. This is because though stress is generated in each producing process such as burying polysilicon into trench and laser annealing, the direction of each stress is dispersed.

This makes possible to avoid difficulties in wafer handling. The smaller the wafer warpage, the thinner the wafer can be. Furthermore, it is possible to avoid a possibility that the on-resistance of the semiconductor device is increased by the piezoelectric effect. Furthermore, heat dissipation and device characteristics are improved.

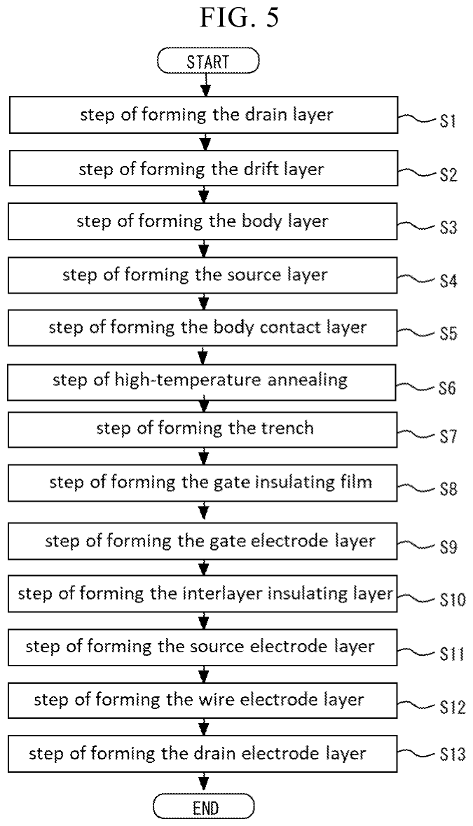

Next, a method of producing the semiconductor device 1 will be described with reference to FIG. 5. FIG. 5 is a flowchart illustrating the method for producing the semiconductor device according to the first embodiment.

As shown in FIG. 5, the semiconductor device 1 is produced through a step of forming the drain layer, a step of forming the drift layer, a step of forming the body layer, a step of forming the source layer, a step of forming the body contact layer, a step of high-temperature annealing, a step of forming the trench, a step of annealing, a step of forming the gate insulating film, a step of forming the gate electrode layer, a step of forming the interlayer insulating layer, a step of forming the source electrode layer, a step of forming the wire electrode layer, and a step of forming the drain electrode layer.

The step of forming the drain layer is performed in a step S1. A substrate is formed as the drain layer 2 in the step of forming the drain layer. Thereafter, the step of forming the drift layer is performed in a step S2. In the step of forming the drift layer, the epitaxial layer is formed as the drift layer 3.

Thereafter, the step of forming the body layering is performed in a step S3. The plurality of body layers 4 are formed by an epitaxial method or an ion implantation technique in the step of forming the body layer. The step of forming the source layers is performed in a step S4. The plurality of source layers 5 are formed as a source layer by the ion implantation technique in the step of forming the source layer.

Thereafter, the step of forming the body contact layers is performed in a step S5. The plurality of body contact layers 6 are formed by the ion implantation technique in the step of forming the body contact layers. Thereafter, the high-temperature annealing step is performed in a step S6. The annealing step is carried out in a high-temperature environment in order to activate the impurity elements (dopants) ion-implanted in the annealing step.

Thereafter, the step of forming the trench is performed in a step S7. A plurality of trenches T are formed by etching in the step of forming the trench. In this case, multiple trench T are formed by etching the drift layer 3 and the body layers 4.

Thereafter, the step of forming the gate electrode layers is performed in a step S8. In step of forming the gate electrode layers, the plurality of gate insulating films 7 are formed by a thermal oxidation method. The step of forming the gate-electrode layer is performed in a step S9. The plurality of gate electrode trench stripes 8 are formed in the step of forming the gate electrode layer.

The step of forming the interlayer insulating layer interlayer is performed in a step 10. The interlayer insulating layer 9 is formed by CVD method in the step of forming the interlayer insulating layer interlayer. Thereafter, the step of forming the source electrode layers is performed in a step S11. The plurality of source electrode layers 10 are formed of the film of Ni or the like with the sputtering method and by heat treatment in the step of forming the source electrode layers. Thereafter, the step of forming the wire electrode layer is performed in a step S12. The wire electrode layer 11 is formed of an aluminum alloy or the like by the sputtering method in the step of forming the wire electrode layer.

Thereafter, the step of forming the drain electrode layer is performed in a step S13. The drain electrode layer 12 is formed of the film of Ni or the like with the sputtering method and by heat treatment in the drain electrode layer forming step.

According to the first embodiment described above, it is possible to provide a semiconductor device that facilitates the production of the semiconductor with a thinner wafer thickness by suppressing the wafer warpage and decreasing the difficulty of wafer handling, reduces on-resistance and improves heat dissipation.

It is also possible to suppress the generation of the piezoelectric field. Therefore, it is possible to suppress the non-uniformity caused by the piezoelectric field. This makes it possible to obtain a high-quality semiconductor device 1 with suppressed variation in performance.

Further, the first conductivity type may be p type, the second conductivity type may be n type. In this case, it is also possible to provide a semiconductor device that facilitates the production of the semiconductor with a thinner wafer thickness by suppressing the wafer warpage and decreasing the difficulty of wafer handling, reduces on-resistance and improves heat dissipation.

Further, the semiconductor device 1 may be a trenched IGBT. In this case, the drain layer 2 as a first impurity layer may be a p⁺ type collector layer. The source layers 5 as a second impurity layer may be used as emitter layers. The source electrode layers 10 as a first electrode layer may be the emitter electrode layers. The drain electrode layer 12 as a second electrode layer may be a collector electrode layer.

Further, the semiconductor device 1 may be a semiconductor device including a junction barrier Schottky diode region. The semiconductor device 1 may be a semiconductor device including a merged pin Schottky diode region. In this case, it is possible to adopt the configuration required for Schottky diode as the wiring electrode layer 11 to the anode and as the drain electrode layer 12 to the cathode for example, except for unnecessary structures such as the source layers 5 and the source electrode layers 10.

### Embodiment 2

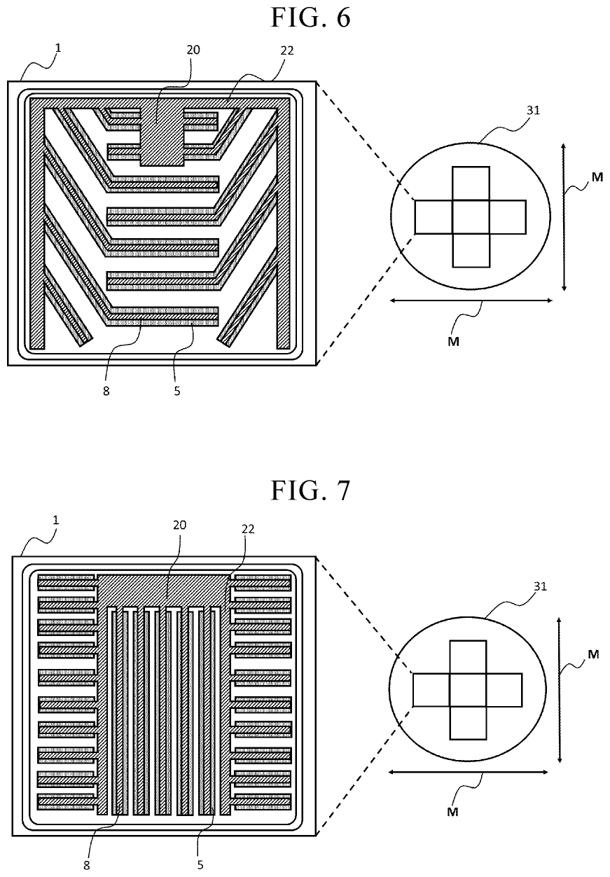

FIG. 6 is a schematic top view of a semiconductor device according to the second embodiment. As shown in FIG. 6, a gate pad 20, a gate electrode wiring 22 and a plurality of gate electrode trench stripes 8 are formed on the semiconductor device 1.

Further, the plurality of source layers 5 are formed to adjacent to the plurality of gate electrode trench stripes 8. Some of the plurality of gate electrode trench stripes 8 are connected directly to the gate pad 20. Also, some of the plurality of gate electrode trench stripes 8 are directly connected to the gate electrode wiring 22. As shown in FIG. 6, the direction of the plurality of gate electrode trench stripes 8 are arranged in three directions.

4H silicon carbide constituting the drift layer is hexagonal crystal of which the first major plane is the (0001) Si plane as shown in FIG. 3 part (1). A gate channel portion of a trench-type MOSFET is formed perpendicularly on the main plane. When this happens, for example the (1−100) plane of the crystal orientation is desirable for the vertical plane formed as shown in FIG. 3 part (2).

Since the hexagonal crystal is six-fold symmetry, it is desirable that the (10−10) plane and the (1−100) plane forming 60 degrees each other as other crystal surface as shown in FIG. 4 part (1). The outer shape of 4H silicon carbide substrate is shown in FIG. 4 part (3). Normally, the orientation flat for confirming the direction of the substrate and the (1−100) plane shown in FIG. 4 part (1) are generally the same. The angle between the orientation flat and the (1−100) plane of the crystal varies by +5 degrees due to producing errors. Therefore, it is desirable that the three longitudinal directions of the gate electrode trench stripes 8 be positioned between −5 degrees to 5 degrees, between 55 degrees to 65 degrees, or between 115 degrees to 125 degrees against the orientation flat. This can increase channel mobility.

As shown in FIG. 6, the three longitudinal directions of the plurality of gate electrode trench stripes 8 desirably be arranged substantially parallel to the (11−20) plane, the (1−210) plane and the (−2110) plane of hexagonal crystal of the 4H silicon carbide. Alternatively, it is desirable that each three longitudinal directions of the plurality of gate electrode trench stripes 8 be arranged substantially parallel to three planes of hexagonal crystal of the (1−100) planes, the (10−10) planes, and the (0−110) planes of 4H silicon carbide. This improves channel mobility.

Epitaxial growth of 4H silicon carbide may be grown with hexagonal crystals inclined by 4 or 8 degrees. Thus, for example, the (10−10) plane, the (0−110) plane, the (1−210) plane and the (−2110) plane of the cubic of 4H silicon carbide slightly changed from the angle in a top view.

For example, in the case of epitaxial growth with 4 degrees gradient, the angle formed by the (1−210) plane and the (−2110) plane is 30 degrees as shown in FIG. 4 part (1) in a top view of the cubic crystal. Meanwhile, it is 29.94 degrees in a top view of the wafer.

The three longitudinal directions of the plurality of gate electrode trench stripes 8 may be parallel (substantially parallel) to each plane including such errors and other production errors. Desirably, the three longitudinal directions of the plurality of gate electrode trench stripes 8 may be arranged in parallel (substantially parallel) with each plane within +0.2 degrees.

The angle formed by the orientation flat and the (1−100) plane of the crystal has variation of +5 degrees due to producing errors. Therefore, the three longitudinal directions of the gate electrode trench stripes 8 may be arranged between 25 degrees to 35 degrees, between 85 degrees to 95 degrees, or between 145 degrees to 155 degrees to the orientation flat. This allows channel mobility increased.

In the case of a notch-type wafer without an orientation flat, a plane perpendicular to a plane from the notch toward the center of the wafer can be regarded as an orientation flat (regarded orientation flat). The three longitudinal directions of the gate electrode trench stripes 8 may be arranged between 25 degrees and 35 degrees, between 85 degrees and 95 degrees, or between 145 degrees and 155 degrees to the regarded orientation flat. This allows channel mobility increased.

The gate pad 20 is disposed in a central region of one side of the semiconductor device 1. The gate electrode wiring 22 are arranged so as to partially surround the gate electrode trench stripes 8 and the gate pad 20 along the four sides of the semiconductor device 1.

Since the other configuration is the same as that of the first embodiment, the description thereof is omitted.

FIG. 6 also shows a wafer 31 in which the semiconductor device 1 according to the first embodiment before being segmented is arranged in an array. Both the horizontal axis direction M and the vertical axis direction M of the wafer 31, the wafer warpage is moderate.

In a trench stripe trench-type MOSFET in which the plurality of gate electrode trench stripes 8 are arranged so that the longitudinal direction faces at least two directions, anisotropy of warpage of the wafer is reduced. In particular, when the sum of the lengths of the gate electrode trench stripes in each of the three directions is equal, the anisotropy of the warpage of the wafer is reduced.

This is because though stress is generated in each producing process such as burying polysilicon into trench and laser annealing, the direction of each stress is dispersed.

This makes possible to avoid difficulties in wafer handling. The smaller the wafer warpage, the thinner the wafer can be. Furthermore, it is possible to avoid a possibility that the on-resistance of the semiconductor device is increased by the piezoelectric effect. Furthermore, heat dissipation and device characteristics are improved.

### Embodiment 3

FIG. 7 is a schematic top view of a semiconductor device according to the third embodiment. As shown in FIG. 7, a gate pad 20, a gate electrode wiring 22 and a plurality of gate electrode trench stripes 8 are formed on the semiconductor device 1.

Further, the plurality of source layers 5 are formed to adjacent to the plurality of gate electrode trench stripes 8. Some of the plurality of gate electrode trench stripes 8 are connected directly to the gate pad 20.

Some of the plurality of gate electrode trench stripes 8 are directly connected to the gate electrode wiring 22. As shown in FIG. 7, the direction of the plurality of gate electrode trench stripes 8 are arranged in three directions.

Since the other configuration is the same as that of the first embodiment, the description thereof is omitted.

FIG. 7 also shows a wafer 31 in which the semiconductor device 1 according to the first embodiment before being segmented is arranged in an array. Both the horizontal axis direction M and the vertical axis direction M of the wafer 31, the wafer warpage is moderate.

In a trench stripe trench-type MOSFET in which the plurality of gate-electrode trench stripes 8 are arranged so that the longitudinal direction faces at least two directions, anisotropy of warpage of the wafer is reduced. In particular, when the sum of the lengths of the gate electrode trench stripes in each of the three directions is equal, the anisotropy of the warpage of the wafer is reduced.

This is because though stress is generated in each producing process such as burying polysilicon into trench and laser annealing, the direction of each stress is dispersed.

This makes possible to avoid difficulties in wafer handling. The smaller the wafer warpage, the thinner the wafer can be. Furthermore, it is possible to avoid a possibility that the on-resistance of the semiconductor device is increased by the piezoelectric effect. Furthermore, heat dissipation and device characteristics are improved.

### Embodiment 4

FIG. 8 is a schematic top view of a semiconductor device according to the fourth embodiment. As shown in FIG. 8, a gate pad 20, a gate electrode wiring 22 and a plurality of gate electrode trench stripes 8 are formed on the semiconductor device 1.

Further, the plurality of source layers 5 are formed to adjacent to the plurality of gate electrode trench stripes 8. Some of the plurality of gate electrode trench stripes 8 are connected directly to the gate pad 20.

Some of the plurality of gate electrode trench stripes 8 are directly connected to the gate electrode wiring 22. As shown in FIG. 8, the direction of the plurality of gate electrode trench stripes 8 are arranged in two directions.

The gate pad 20 is disposed in the one corner of neighboring region of the semiconductor device 1. Further, the gate electrode wiring 22 is arranged so as to cross diagonally the semiconductor device 1 from the corner of the semiconductor device 1 where the gate pad 20 is arranged toward the opposite corners.

Since the other configuration is the same as that of the first embodiment, the description thereof is omitted.

FIG. 8 also shows a wafer 31 in which the semiconductor device 1 according to the first embodiment before being segmented is arranged in an array. Both the horizontal axis direction M and the vertical axis direction M of the wafer 31, the wafer warpage is moderate.

In a trench stripe trench-type MOSFET in which the plurality of gate electrode trench stripes 8 are arranged so that the longitudinal direction faces at least two directions, anisotropy of warpage of the wafer is reduced. In particular, when the sum of the lengths of the gate electrode stripes in each of the three directions is equal, the anisotropy of the warpage of the wafer is reduced.

This is because though stress is generated in each producing process such as burying polysilicon into trench and laser annealing, the direction of each stress is dispersed.

This makes possible to avoid difficulties in wafer handling. The smaller the wafer warpage, the thinner the wafer can be. Furthermore, it is possible to avoid a possibility that the on-resistance of the semiconductor device is increased by the piezoelectric effect. Furthermore, heat dissipation and device characteristics are improved.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. A semiconductor device comprising:
a drain layer formed of a first conductivity semiconductor;
a drift layer formed of the first conductivity semiconductor and on the drain layer; and
a plurality of trench stripes having longitudinal directions and lateral directions formed of a second conductivity semiconductor and formed on the drift layer,
wherein the longitudinal directions of the plurality of trench stripes are disposed toward at least two directions.

2. The semiconductor device according to claim 1,
wherein the drain layer and the drift layer are formed of silicon carbide.

3. The semiconductor device according to claim 1, further comprising:
a gate insulating film; and
a gate electrode,
wherein the gate electrode comprises a gate pad, a gate electrode wiring directly connected to the gate pad, and a plurality of gate electrode trench stripes that are include in the plurality of trench stripes,
wherein a first plurality of the plurality of gate electrode trench stripes is directly connected to the gate pad and a second plurality of the plurality of gate electrode trench stripes is directly connected to the gate electrode wiring.

4. The semiconductor device according to claim 1,
wherein the longitudinal directions of the plurality of trench stripes are disposed toward three directions.

5. The semiconductor device according to claim 3,
wherein the longitudinal directions of the plurality of gate electrode trench stripes disposed toward three directions.

6. The semiconductor device according to claim 3,
wherein the semiconductor device is square in a top view and the gate pad is disposed in a central region of any one side of the semiconductor device.

7. The semiconductor device according to claim 3,
wherein the semiconductor device is square in a top view and the gate pad is disposed in any one corner of neighboring region of the semiconductor device.

8. The semiconductor device according to claim 4,
wherein the drain layer and the drift layer are formed of 4H silicon carbide,
wherein the three longitudinal directions, are respectively arranged substantially parallel to a (11−20) plane, a (1−210) plane and a (−2110) plane of hexagonal crystal of the 4H silicon carbide.

9. The semiconductor device according to claim 5,
wherein the drain layer and the drift layer are formed of 4H silicon carbide,
wherein the three longitudinal directions, are respectively arranged substantially parallel to a (11−20) plane, a (1−210) plane and a (−2110) plane of hexagonal crystal of the 4H silicon carbide.

10. The semiconductor device according to claim 4,
wherein the drain layer and the drift layer are formed of 4H silicon carbide,
wherein the three longitudinal directions, are respectively arranged substantially parallel to a (1−100) plane, a (10−10) plane and a (0−110) plane of hexagonal crystal of the 4H silicon carbide.

11. The semiconductor device according to claim 5,
wherein the drain layer and the drift layer are formed of 4H silicon carbide,
wherein the three longitudinal directions, are respectively arranged substantially parallel to a (1−100) plane, a (10−10) plane and a (0−110) plane of hexagonal crystal of the 4H silicon carbide.

12. The semiconductor device according to claim 3,
wherein the gate electrode wiring is arranged so as to surround the gate pad and the plurality of gate electrode trench stripes.

13. The semiconductor device according to claim 4,
wherein the three longitudinal directions, are positioned between −5 degrees to 5 degrees, between 55 degrees to 65 degrees, or between 115 degrees to 125 degrees against an orientation flat of a wafer before being segmented.

14. The semiconductor device according to claim 5,
wherein the three longitudinal directions, are positioned between −5 degrees to 5 degrees, between 55 degrees to 65 degrees, or between 115 degrees to 125 degrees against an orientation flat of a wafer before being segmented

15. The semiconductor device according to claim 4,
wherein the three longitudinal directions, are positioned between 25 degrees to 35 degrees, between 85 degrees to 95 degrees, or between 145 degrees to 155 degrees against an orientation flat of a wafer before being segmented.

16. The semiconductor device according to claim 5,
wherein the three longitudinal directions, are positioned between 25 degrees to 35 degrees, between 85 degrees to 95 degrees, or between 145 degrees to 155 degrees against an orientation flat of a wafer before being segmented

17. The semiconductor device according to claim 4,
wherein the sum of the lengths of the plurality of trench stripes or the plurality of gate electrode trench stripes in each of the three directions is equal.

18. The semiconductor device according to claim 5,
wherein the sum of the lengths of the plurality of trench stripes or the plurality of gate electrode trench stripes in each of the three directions is equal

19. The semiconductor device according to claim 1, wherein a junction barrier Schottky diode region is implemented as an electrode formed so as to cover at least a region of the plurality of trench stripes.

20. The semiconductor device according to claim 1, wherein a merged pin Schottky diode region is implemented as an electrode formed so as to cover the at least a region of the plurality of trench stripes, wherein a second semiconductor region having a second conductivity type is in contact with the region of plurality of trench stripes in one of the longitudinal directions,
wherein a concentration of the second conductivity type of the second semiconductor region is higher than a concentration of the second conductivity type of the region of the plurality of trench stripes.
